(19) United States
(12) Patent Application Publication
(10) Pub. No.: US 2026/0271276 A1
(43) Pub. Date: Sep. 10, 2026

(54) SEMICONDUCTOR DEVICE AND FABRICATION METHOD THEREOF

(71) Applicant: Yangtze Memory Technologies Co., Ltd., Wuhan (CN)

(72) Inventors: Wenxiang XU, Wuhan (CN); Hongye HUANG, Wuhan (CN); Chenxi LING, Wuhan (CN); Yiming WANG, Wuhan (CN); Zhaoyun TANG, Wuhan (CN)

(21) Appl. No.: 19/265,755

(22) Filed: Jul. 10, 2025

Related U.S. Application Data
(63) Continuation of application No. PCT/CN2025/080674, filed on Mar. 5, 2025.

(51) Int. Cl. H10B 12/00

(52) U.S. Cl. CPC H10B 12/482; H10B 12/05; H10B 12/315

(57) ABSTRACT

Methods, devices, systems, and techniques for managing conductive structure in semiconductor devices are provided. In one aspect, a semiconductor device includes a first and a second vertical transistor includes a first semiconductor body and a second semiconductor body extending along a first direction. The semiconductor device also includes a first bit line including a first segment, a first bridge structure, and a second segment arranged along a second direction perpendicular to the first direction, the first bridge structure connecting the first segment and the second segment, where the first bit line extends along the second direction, the first semiconductor body is adjacent to the second semiconductor body along the second direction, the first segment is in contact with a first side of the first semiconductor body along the first direction, and the second segment is in contact with a first side the second semiconductor body along the first direction.

### CROSS-REFERENCE TO RELATED APPLICATIONS

This application is a continuation of International Application No. PCT/CN2025/080674, filed on Mar. 5, 2025, the disclosure of which is hereby incorporated by reference in its entirety.

### TECHNICAL FIELD

The present disclosure relates to semiconductor devices and fabrication processes for semiconductor devices.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array. The memory cells can include vertical structures, e.g., vertical transistors.

### SUMMARY

The present disclosure describes methods, devices, systems and techniques for managing vertical structures in three-dimensional (3D) semiconductor devices.

One aspect of the present disclosure features a semiconductor device. The semiconductor device includes a first vertical transistor including a first semiconductor body extending along a first direction; a second vertical transistor including a second semiconductor body extending along the first direction; and a first bit line including a first segment, a first bridge structure, and a second segment arranged along a second direction perpendicular to the first direction, the first bridge structure connecting the first segment and the second segment, where: the first bit line extends along the second direction, the first semiconductor body is adjacent to the second semiconductor body along the second direction, the first segment is in contact with a first side of the first semiconductor body along the first direction, and the second segment is in contact with a first side the second semiconductor body along the first direction.

In some implementations, a length of the first bridge structure is greater than a distance between the first semiconductor body and the second semiconductor body along the second direction.

In some implementations, a width of the first bridge structure is smaller or equal to a width of the first segment of the first bit line along a third direction perpendicular to the first direction and the second direction.

In some implementations, a cross-section of the first bridge structure perpendicular to the second direction includes a rectangular shape.

In some implementations, the semiconductor device further includes an isolation structure extending along the first direction, where the isolation structure is between the first semiconductor body and the second semiconductor body along the second direction.

In some implementations, the isolation structure includes a first separation structure in at least a portion of the isolation structure; and an air gap that is in contact with a side of the bridge structure along the first direction, where the air gap is between the first semiconductor body and the second semiconductor body along the second direction.

In some implementations, the semiconductor device includes a first gate electrode extending along the first direction coupled to the first semiconductor body, where the first gate electrode includes a first end and a second end opposite to each along the first direction, where an end of the air gap is between the first end and the second end of the first gate electrode, and where the end of the air gap is in contact with the first separation structure along the first direction.

In some implementations, the first separation structure of the isolation structure further includes a second gate electrode extending along the first direction, where the second gate electrode is coupled to the first semiconductor body; and a third gate electrode extending along the first direction, where the third gate electrode is coupled to the second semiconductor body, and where the second gate electrode and the third gate electrode are separated by a first dielectric structure.

In some implementations, the first separation structure of the isolation structure further includes a second dielectric structure extending along the first direction, where the second dielectric structure electrically isolates the first semiconductor body and the second semiconductor body.

In some implementations, the first separation structure of the isolation structure includes a group of at least one third dielectric structure extending along the first direction and at least one fourth gate electrode extending along the first direction, where the third dielectric structure electrically isolates the first semiconductor body and the second semiconductor body, and where the fourth gate electrode is coupled to either the first semiconductor body or the second semiconductor body.

In some implementations, the semiconductor device further includes a third vertical transistor including a third semiconductor body extending along a first direction; a fourth vertical transistor including a fourth semiconductor body extending along the first direction, the third semiconductor body is adjacent to the fourth semiconductor body along the second direction; and a second bit line extending the second direction, where the second bit line includes a third segment, a second bridge structure, and a fourth segment arranged along the second direction, the third segment is in contact with the third semiconductor body along the first direction, and the fourth segment is in contact with the fourth semiconductor body along the first direction, where the second bridge structure connects the third segment and the fourth segment, where the first bit line and the second bit line are separated by a first dielectric structure along a third direction perpendicular to the first direction and the second direction, and the first bridge structure of the first bit line and the second bridge structure of the second bit line are aligned along the third direction.

In some implementations, the semiconductor device further includes a fifth vertical transistor including a fifth semiconductor body extending along a first direction; a sixth vertical transistor including a sixth semiconductor body extending along the first direction, the fifth semiconductor body is adjacent to the sixth semiconductor body along the second direction; and a third bit line extending the second direction, where the third bit line includes a fifth segment, a third bridge structure, and a sixth segment arranged along the second direction, the fifth segment is in contact with the fifth semiconductor body along the first direction, and the sixth segment is in contact with the sixth semiconductor body along the first direction, where the third bridge structure connects the fifth segment and the sixth segment, where the first bit line and the third bit line are separated by a second dielectric structure along a third direction perpendicular to the first direction and the second direction, and the first bridge structure of the first bit line and the third bridge structure of the third bit line are offset along the third direction.

In some implementations, the first vertical transistor further includes a first storage structure connected to a second side of the first semiconductor body along the first direction, where the first side and the second of the first semiconductor body are on opposite side along the first direction; and the second vertical transistor further includes a second storage structure connected to a second side of the second semiconductor body along the first direction, where the first side and the second of the second semiconductor body are on opposite side along the first direction.

In some implementations, the semiconductor device further includes a seventh vertical transistor including a seventh semiconductor body extending along the first direction, where the seventh semiconductor body is in contact with the first segment of the first bit line; and an eighth vertical transistor including an eighth semiconductor body extending along the first direction, where the eighth semiconductor body is in contact with the second segment of the first bit line, and where the first semiconductor body and the second semiconductor body are between the seventh semiconductor body and the eighth semiconductor body along the second direction.

Another aspect of the present disclosure features a method of forming a semiconductor device. The method includes forming a first vertical transistor including a first semiconductor body extending along a first direction; forming a second vertical transistor including a second semiconductor body extending along the first direction; and forming a first bit line including a first segment, a first bridge structure, and a second segment arranged along a second direction perpendicular to the first direction, the first bridge structure connecting the first segment and the second segment, where: the first bit line extends along the second direction, the first semiconductor body is adjacent to the second semiconductor body along the second direction, the first segment is in contact with a first side of the first semiconductor body along the first direction, and the second segment is in contact with a first side the second semiconductor body along the first direction.

In some implementations, the method further includes providing a semiconductor substrate; etching a first portion of the semiconductor substrate from a first side of the semiconductor substrate to form first trenches, where the first trenches extend along the second direction, where semiconductor structures are formed by a remaining portion of the semiconductor substrate; removing a portion of the semiconductor structures to form a second trench, where the second trench extends along a third direction perpendicular to the first direction and the second direction; and filling a dielectric material in the first trenches and the second, where first isolation structures are defined by the dielectric material in the first trenches, and a second isolation structure is defined by the dielectric material in the second trench.

In some implementations, the method further includes etching a second portion of the semiconductor substrate from the first side of the semiconductor substrate to form third trenches, where the third trenches extend along the third direction; forming first structures in a portion of the third trenches, where each of the first structures includes two conductive structures extending along the first direction, and where the two conductive structures are separated by an isolation structure along the second direction; and forming second structures in a remaining portion of the third trenches, where each of the second structures includes a dielectric structure.

In some implementations, the first bridge structure includes a conductive material, and where forming the first bridge structure includes thinning down the semiconductor substrate from a second side of the semiconductor substrate, where the isolation structure extend through the semiconductor substrate, where the first side and the second side of the semiconductor substrate are on opposite side along the first direction; etching a third portion of the semiconductor substrate and a portion of the isolation structure from the second side to form a fourth trench; and depositing the conductive material in the fourth trench to form the first bridge structure.

In some implementations, the method further includes removing a portion of the first structure from an end of the first structure to from a first space, the end of the first structure being closer to the second side of the semiconductor substrate than the first side of the semiconductor substrate; removing a portion of the second structure from an end of the second structure to from a second space, the end of the second structure being closer to the second side of the semiconductor substrate than the first side of the semiconductor substrate; and removing a portion of the isolation structure from an end of the isolation structure to from a third space, the end of the isolation structure being closer to the second side of the semiconductor substrate than the first side of the semiconductor substrate.

A further aspect of the present disclosure features a memory system. The memory system includes a memory device and a memory controller coupled to the memory device and configured to control the memory device. The memory device includes a first vertical transistor including a first semiconductor body extending along a first direction; a second vertical transistor including a second semiconductor body extending along the first direction; and a first bit line including a first segment, a first bridge structure, and a second segment arranged along a second direction perpendicular to the first direction, the first bridge structure connecting the first segment and the second segment, where: the first bit line extends along the second direction, the first semiconductor body is adjacent to the second semiconductor body along the second direction, the first segment is in contact with a first side of the first semiconductor body along the first direction, and the second segment is in contact with a first side the second semiconductor body along the first direction.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a cross-sectional view of an example 3D semiconductor device.

FIG. 2A illustrates a top view of example 3D semiconductor devices.

FIG. 2B illustrates a cross-sectional view of example 3D semiconductor devices.

FIGS. 3A-3B illustrate top views of example 3D semiconductor devices of FIG. 2B.

FIGS. 4A to 4F show cross-sectional views of 3D semiconductor device.

FIGS. 5A to 5K illustrate an example process of fabricating a semiconductor device.

FIGS. 6A to 6I illustrate an example process of fabricating a semiconductor device.

FIG. 7 illustrates a flow chart of an example process of manufacturing a semiconductor structure.

FIG. 8 illustrates a block diagram of an example system having one or more semiconductor devices.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to the demand for cheaper memory devices with higher density, a memory device (e.g., a DRAM memory) can be formed with a vertical transistor and a high aspect ratio. The vertical channel selector tube and the high aspect ratio of such memory devices may pose challenges to the manufacturing process. For example, the high aspect ratio of the vertical transistors can lead to internal stress during the fabrication process. This internal stress can cause dislocation of the semiconductor material within the semiconductor body of the vertical transistors, resulting in higher leakage current. In other words, the internal stress of the vertical transistors may increase device defects. Therefore, a semiconductor structure that can solve the aforementioned issues is desirable.

In one or more implementations of the present disclosure, an example semiconductor device is provided. The semiconductor device includes a first vertical transistor including a first semiconductor body extending along a first direction and a second vertical transistor including a second semiconductor body extending along the first direction. The semiconductor device also includes a first bit line including a first segment, a first bridge structure, and a second segment arranged along a second direction perpendicular to the first direction, the first bridge structure connecting the first segment and the second segment, where the first bit line extends along the second direction, the first semiconductor body is adjacent to the second semiconductor body along the second direction, the first segment is in contact with a first side of the first semiconductor body along the first direction, and the second segment is in contact with a first side the second semiconductor body along the first direction.

Implementations of the present disclosure can provide one or more of the following technical advantages and/or benefits. First, the bit line of the semiconductor device is separated into one or more segments. The separation of the bit line can help to relieve internal stress during the fabrication process. In other words, the separation of the bit line of the semiconductor device can help to reduce leakage current and defects in the memory device. Second, bridge structures are used to connect the segments of the bit lines. The bridge structures are conductive to maintain the electrical connection of the segments of the bit lines, which can be used to control the vertical transistors connected to the bit lines. Third, the separation of the bit line and the fabrication of the bridge structure can be easily integrated into the current manufacturing process without increasing the fabrication cost.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

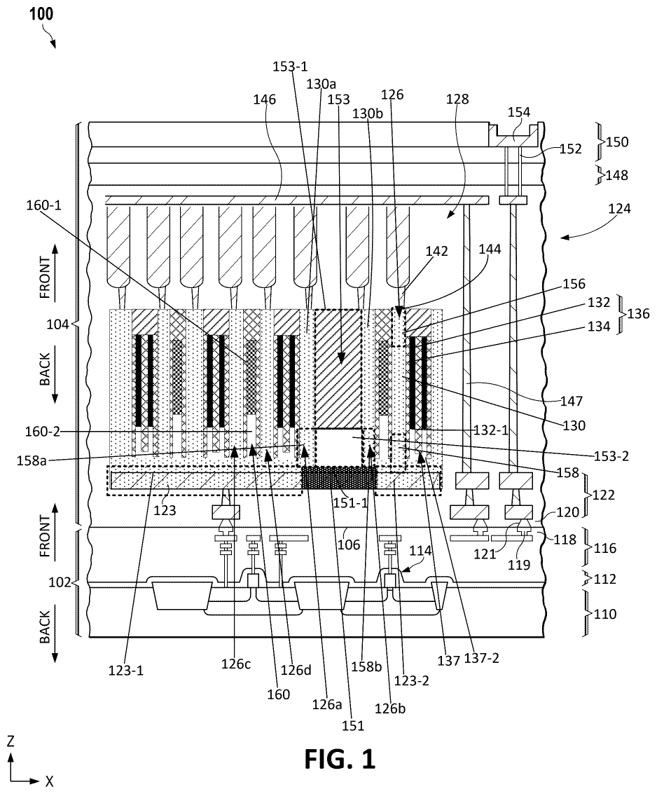

It is noted that X, Y, and Z axes (also referred to as X, Y, and Z directions) are included in FIG. 1 to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1 illustrates a side view of a cross-section of an example 3D semiconductor device 100. The 3D semiconductor device 100 can be a 3D dynamic random-access memory (DRAM). It is understood that FIG. 1 is for illustrative purposes only and may not necessarily reflect the actual device structure (e.g., interconnections) in practice. In some implementations, the 3D semiconductor device 100 is a bonded chip including a first semiconductor structure 102 and a second semiconductor structure 104 stacked over the first semiconductor structure 102. The first and second semiconductor structures 102 and 104 can be jointed at bonding interface 106 therebetween.

As shown in FIG. 1, the first semiconductor structure 102 can include a substrate 110, which can include silicon (e.g., single crystalline silicon, c-Si), SiGe, GaAs, Ge, SOI, or any other suitable materials. The first semiconductor structure 102 can include peripheral circuits 112 on and/or in the substrate 110. In some implementations, the peripheral circuits 112 include a plurality of transistors 114 (e.g., planar transistors and/or 3D transistors). Trench isolations (e.g., shallow trench isolations (STIs)) and doped regions (e.g., wells, sources, and drains of transistors 114) can be formed on or in the substrate 110 as well. In some examples, the peripheral circuits 112 are formed using complementary metal-oxide-semiconductor (CMOS) technology, and the first semiconductor structure 102 can be also formed on a semiconductor die that can be referred to as a control die or a CMOS die 102.

In some implementations, the first semiconductor structure 102 further includes an interconnect layer 116 above the peripheral circuits 112 to transfer electrical signals to and from the peripheral circuits 112. The interconnect layer 116 can include a plurality of interconnects (also referred to herein as “contacts”), including lateral interconnect lines and VIA contacts. The interconnect layer 116 can further include one or more interlay dielectric (ILD) layers in which the interconnect lines and via contacts can form. That is, the interconnect layer 116 can include interconnect lines and via contacts in multiple ILD layers. In some implementations, peripheral circuits 112 are coupled to one another through the interconnects in the interconnect layer 116. The interconnects in interconnect layer 116 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As shown in FIG. 1, the first semiconductor structure 102 has a front side and a back side, and the first semiconductor structure 102 can further include a bonding layer 118 at the back side at the bonding interface 106 and above the interconnect layer 116 and the peripheral circuits 112. The bonding layer 118 can include a plurality of bonding contacts 119 and dielectrics electrically isolating the bonding contacts 119. The bonding contacts 119 can include conductive materials, such as Cu. The remaining area of the bonding layer 118 can be formed with dielectric materials, such as silicon oxide. The bonding contacts 119 and surrounding dielectrics in the bonding layer 118 can be used for hybrid bonding. Similarly, as shown in FIG. 1, the second semiconductor structure 104 can also include a bonding layer 120 at the bonding interface 106 and above the bonding layer 118 of the first semiconductor structure 102. The bonding layer 120 can include a plurality of bonding contacts 121 and dielectrics electrically isolating the bonding contacts 121. The bonding contacts 121 can include conductive materials, such as Cu. The remaining area of the bonding layer 120 can be formed with dielectric materials, such as silicon oxide. The bonding contacts 121 and surrounding dielectrics in the bonding layer 120 can be used for hybrid bonding. The bonding contacts 121 can be in contact with the bonding contacts 119 at the bonding interface 106. In some implementations, the bonding layer 120 includes a dielectric layer opposing memory cells (e.g., DRAM cells) 124 with a bit line 123 positioned between the dielectric layer and the memory cells 124, as shown in FIG. 1. The dielectric layer can include the bonding interface 106 having the bonding contacts 121.

The second semiconductor structure 104 can be bonded on top of the first semiconductor structure 102 in a face-to-face manner at the bonding interface 106. In some implementations, the bonding interface 106 is disposed between the bonding layers 120 and 118 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, the bonding interface 106 is the place at which bonding layers 120 and 118 are met and bonded. In some examples, the bonding interface 106 can be a layer with a certain thickness that includes the top surface of the bonding layer 118 of the first semiconductor structure 102 and the bottom surface of the bonding layer 120 of the second semiconductor structure 104.

In some implementations, the second semiconductor structure 104 further includes an interconnect layer 122 including bit lines 123 above the bonding layer 120 to transfer electrical signals. The interconnect layer 122 can include a plurality of interconnects, such as mid end of line (MEOL) interconnects and back end of line (BEOL) interconnects. In some implementations, the interconnects in interconnect layer 122 also include local interconnects, such as the bit lines 123 and word line contacts (not shown). The interconnect layer 122 can further include one or more ILD layers in which the interconnect lines and via contacts can form. The interconnects in the interconnect layer 122 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

In some implementations, the peripheral circuits 112 include a word line driver/row decoder coupled to the word line contacts in the interconnect layer 122 through the bonding contacts 121 and 119 in the bonding layers 120 and 118 and the interconnect layer 116. In some implementations, the peripheral circuits 112 include a bit line driver/column decoder coupled to the bit lines 123 and bit line contacts in the interconnect layer 122 through the bonding contacts 121 and 119 in the bonding layers 120 and 118 and the interconnect layer 116. In some implementations, the bit line 123 is a metal bit line, as opposed to semiconductor bit lines (e.g., doped silicon bit lines). For example, the bit line 123 may include W, Co, Cu, Al, or any other suitable metals having higher conductivities than doped silicon. In some implementations, the bit line contact is an ohmic contact as opposed to a Schottky contact.

In some implementations, the bit line 123 is made of a composite conductive material that can be based on a metallic material (e.g., W, Co, Cu, Al) and a semiconductor material (e.g., Si). For example, the composite conductive material can include metal silicide, e.g., such as WSi, CoSi, CuSi, AlSi, or any other suitable metal silicides having higher conductivities than doped silicon.

In some implementations, the second semiconductor structure 104 includes a DRAM device in which memory cells are provided in the form of an array of DRAM cells 124 above the interconnect layer 122 and the bonding layer 120. That is, the interconnect layer 122 including the bit lines 123 can be disposed between bonding layer 120 and array of DRAM cells 124. A bit line 123 in the interconnect layer 122 can be coupled to a string of DRAM cells 124. In some implementations, the second semiconductor structure 104 is formed on a semiconductor die and can be referred to as array die 104.

In some implementations, a semiconductor device can include multiple array dies (e.g., the array die 104) and a CMOS die (e.g., the CMOS die 102). The multiple array dies and the CMOS die can be stacked and bonded together. The CMOS die can be respectively coupled to each of the multiple array dies and can respectively drive each of the multiple array dies to operate in the similar manner as the semiconductor device. The semiconductor device can be any suitable device. In some examples, the semiconductor device includes at least a first wafer and a second wafer bonded face to face. The array die can be disposed with other array dies on the first wafer, and the CMOS die can be disposed with other CMOS dies on the second wafer. The first wafer and the second wafer can be bonded together, thus the array dies on the first wafer can be bonded with corresponding CMOS dies on the second wafer. In some examples, the semiconductor device is a chip with at least the array die and the CMOS die bonded together. In an example, the chip is diced from wafers that are bonded together. In another example, the semiconductor device is a semiconductor package that includes one or more semiconductor chips assembled on a package substrate.

Each DRAM cell 124 can include a vertical transistor 126 and a capacitor 128 coupled to the vertical transistor 126. DRAM cell 124 can be a 1T1C cell including one transistor (T) and one capacitor (C). It is understood that DRAM cell 124 may be of any suitable configurations, such as 2T1C cell, 3T1C cell, etc. The vertical transistor 126 can be a MOSFET used to switch a respective DRAM cell 124. In some implementations, the vertical transistor 126 includes a semiconductor body 130 extending vertically (in the Z direction), and a gate structure 136 extends along the Z direction. In a single-gate vertical transistor, the semiconductor body 130 can have a cuboid shape or a cylinder shape. In some implementations, the vertical transistor 126 has a structure including two or more gates, e.g., a two-gates structure, a three-gates structure, or a gate all around (GAA) structure. In some implementations, the gate structure 136 includes a gate electrode 132 and a gate dielectric 134 laterally between the gate electrode and the semiconductor body 130 in a bit line direction (e.g., in the Y direction). In some implementations, the gate structure 136 extends along the Z direction in a first trench structure 137. In some implementations, the vertical transistor 126 can have a first terminal structure 156 in the positive z-direction and a second terminal structure 158 opposite the first terminal structure 156 in the negative z-direction, as shown in FIG. 1. As shown in FIG. 1, a portion of the first trench structure 137 can include the gate structure 136, whereas a remaining portion of the first trench structure includes an air gap 137-2. The air gap 137-2 in contact with the second terminal structure 158 of the vertical transistor 126 along the X direction.

In some implementations, as shown in FIG. 1, a first bit line 123 is in contact with the second terminal structure 158 along the Z direction. The first bit line 123 includes a first segment 123-1 and a second segment 123-2. The first segment 123-1 of the first bit line 123 and the second segment 123-2 are arranged along the X direction. As shown in FIG. 1, the first segment 123-1 of the first bit line 123 are connected by a first bridge structure 151 along the X direction. In some implementations, the first bridge structure 151 can include a conductive material such as N doped poly Si or metal silicide. As shown in FIG. 1, the semiconductor device 100 includes vertical transistors 126a and 126b having semiconductor bodies 130a and 130b that are adjacent to each other along the X direction. In some implementations, the first segment 123-1 of the first bit line 123 is in contact with a second terminal structure 158a of the semiconductor body 130a and the second segment 123-2 of the first bit line 123 is in contact with a second terminal structure 158b of the semiconductor body 130b along the Z direction.

As shown in FIG. 1, the semiconductor device 100 further includes an isolation structure 153 extending along the Z direction. The isolation structure 153 is between the semiconductor bodies 130a and 130b of the vertical transistors 126a and 126b along the X direction. In some implementations, as shown in FIG. 1, a first portion 153-1 of the isolation structure 153 includes a separation structure, and a second portion of the isolation structure 153 include an air gap 153-2. The air gap 153-2 is in contact with a first end 151-1 of the first bridge structure 151 along the Z direction. In some implementations, a distance from the capacitor 128 to a first end 132-1 of the gate electrode 132 is smaller than a distance from the capacitor 128 to the first end 151-1 of the first bridge structure 151 along the Z direction. In some implementations, an interface 153a between the separation structure 153-1 and the air gap 153-2 is between the first end 132-1 and a second end 132-2 of the gate electrode 132 along the Z direction. The first end 132-1 and the second end 132-2 of the gate electrode 132 is on opposite end of the gate electrode 132 along the Z direction.

In some implementations, the second semiconductor structure 104 includes a dielectric structure 160 between two adjacent vertical transistors. For example, as shown in FIG. 1, vertical transistors 126c and 126d are separated by the dielectric structure 160 along a horizontal direction (e.g., the X direction) perpendicular to the Z direction. In some implementations, a portion 160-1 of the dielectric structure 160 is filled with a dielectric material. A remaining portion 160-2 of the dielectric structure 160 includes an air gap. In some implementations, the dielectric structure 160 is configured to electrically isolated two adjacent vertical transistors to ensure a good electrical performance for each of the two adjacent vertical transistors 126c and 126d.

As shown in FIG. 1, in some implementations, the semiconductor body 130 of the vertical transistor 126 of each memory cell 124 includes opposite ends along the Z direction. In some implementations, the first terminal structure 156 of the vertical transistor 126 and the second terminal structure 158 of the vertical transistor 126 are at the opposite ends of the semiconductor body 130 of the memory cell 124 along the Z direction. In some implementations, the semiconductor body 130 includes a semiconductor material, such as single crystalline silicon, polysilicon, amorphous silicon, Ge, any other semiconductor material, or any combinations thereof. In one example, semiconductor body 130 may include single crystalline silicon. The first terminal structure 156 and the second terminal structure 158 can be doped with N+type dopants (e.g., Phosphorus (P) or Arsenic (As)) or P-type dopants (e.g., Boron (B) or Gallium (Ga)) at a desired doping level. In some implementations, gate dielectric 134 includes dielectric materials, such as silicon oxide, silicon nitride, or high-k dielectrics including, but not limited to, Al2O3, HfO2, Ta2O5, ZrO2, TiO2, or any combination thereof. In some implementations, gate electrode 132 includes a conductive material including, but not limited to W, Co, Cu, Al, TiN, TaN, polysilicon, silicide, or any combination thereof. In some implementations, the gate electrode 132 includes multiple conductive layers, such as a W layer over a TiN layer. In one example, the gate structure 136 may be a “gate oxide/gate poly” gate in which the gate dielectric includes silicon oxide and gate electrode includes doped polysilicon. In another example, gate structure 136 may be an HKMG in which the gate dielectric includes a high-k dielectric and the gate electrode includes a metal.

As described above, since the gate structure 136 may be part of a word line or extend in the word line direction (e.g., the Y direction) as a word line, the second semiconductor structure 104 of the 3D semiconductor device 100 can also include a plurality of word lines each extending in the word line direction. Each of the word lines can be coupled to a row of DRAM cells 124. That is, the bit line 123 and the word line can extend in two perpendicular lateral directions, and the semiconductor body 130 of the vertical transistor 126 can extend in the vertical direction perpendicular to the two lateral directions in which the bit line 123 and the word line extend. Word lines are in contact with word line contacts (not shown). In some implementations, the word lines include conductive materials including, but not limited to W, Co, Cu, Al, TiN, TaN, polysilicon, silicides, or any combination thereof. In some implementations, the word line includes multiple conductive layers, such as a W layer over a TiN layer, as shown in FIG. 1.

In some implementations, as shown in FIG. 1, the vertical transistors 126 can be arranged in a mirror-symmetric manner to increase the density of the memory cells 124 in the bit line direction (the Y direction). As shown in FIG. 1, two adjacent vertical transistors 126c and 126d in the bit line direction are mirror-symmetric to one another with respect to the dielectric structure 160. That is, the second semiconductor structure 104 can include a plurality of the dielectric structure 160 each extending in the X direction in parallel with word lines and disposed between vertical gates of two adjacent rows of the vertical transistors 126. Each of the first trench structures 137 can include two gate structures 136 of two memory cells 124. In some implementations, the rows of vertical transistors 126 separated by the dielectric structure 160 are mirror-symmetric to one another with respect to the dielectric structure 160.

As shown in FIG. 1, in some implementations, a capacitor 128 includes a first electrode 144 above and coupled to the first terminal structure 156 of the vertical transistor 126 via a capacitor contact 142. In some implementations, the capacitor contact 142 is an ohmic contact, such as a metal silicide contact, as opposed to a Schottky contact. For example, the capacitor contact 142 may include metal silicides, such as WSi, CoSi, CuSi, AlSi, or any other suitable metal silicides having higher conductivities than doped silicon. The capacitor 128 can also include a capacitor dielectric above and in contact with the first electrode 144, and a second electrode above and in contact with the capacitor dielectric. That is, the capacitor 128 can be a vertical capacitor in which the electrodes and capacitor dielectric are stacked vertically (in the z-direction), and the capacitor dielectric can be sandwiched between the electrodes. In some implementations, each first electrode is coupled to the first terminal structure 156 of a respective vertical transistor 126 in the same memory cell 124, while all second electrodes are coupled to a common plate 146 coupled to the ground, e.g., a common ground. The capacitor 128 can have a first end in the negative z-direction and a second end opposite the first end in the positive z-direction, as shown in FIG. 1. As shown in FIG. 1, the second semiconductor structure 104 can further include a capacitor contact 147 (e.g., a conductor) in contact with a common plate 146 for coupling the capacitors 128 to the peripheral circuits 112 or to the ground directly. In some implementations, the capacitor contact 147 (e.g., a conductor) extends in the z-direction from the dielectric layer of the bonding layer 120 to couple to the second end of the capacitor 128 via the common plate 146, as shown in FIG. 1. In some implementations, the ILD layer in which the capacitors 128 are formed has the same dielectric material as the two ILD layers into which the semiconductor body 130 extends, such as silicon oxide.

It is understood that the structure and configuration of a capacitor 128 are not limited to the example in FIG. 1 and may include any suitable structure and configuration, such as a planar capacitor, a stack capacitor, a multi-fins capacitor, a cylinder capacitor, a trench capacitor, or a substrate-plate capacitor. In some implementations, the capacitor dielectric includes dielectric materials, such as silicon oxide, silicon nitride, or high-k dielectrics including, but not limited to, Al2O3, HfO2, Ta2O5, ZrO2, TiO2, or any combination thereof. It is understood that in some examples, a capacitor 128 may be a ferroelectric capacitor used in a FRAM cell, and the capacitor dielectric may be replaced by a ferroelectric layer having ferroelectric materials, such as PZT or SBT. In some implementations, the electrodes include conductive materials including, but not limited to W, Co, Cu, Al, TiN, TaN, polysilicon, silicides, or any combination thereof.

As shown in FIG. 1, in some implementations, the vertical transistors 126 are disposed vertically between the capacitors 128 and the bonding interface 106. That is, the vertical transistors 126 can be arranged closer to the peripheral circuits 112 of the first semiconductor structure 102 and the bonding interface 106 than the capacitors 128. Since the bit lines 123 and the capacitors 128 are coupled to opposite ends of the vertical transistors 126, the bit lines 123 (as part of the interconnect layer 122) are disposed vertically between the vertical transistors 126 and the bonding interface 106 As a result, the interconnect layer 122 including bit lines 123 can be arranged close to the bonding interface 106 to reduce the interconnect routing distance and complexity.

In some implementations, the second semiconductor structure 104 further includes a substrate 148 disposed above the DRAM cells 124. The substrate 148 can be part of a carrier wafer. It is understood that in some examples, the substrate 148 may not be included in the second semiconductor structure 104.

As shown in FIG. 1, the second semiconductor structure 104 can further include a pad-out interconnect layer 150 above the substrate 148 and the DRAM cells 124. The pad-out interconnect layer 150 can include interconnects, e.g., contact pads 154, in one or more ILD layers. The pad-out interconnect layer 150 and the interconnect layer 122 can be formed on opposite sides of the DRAM cells 124. The capacitors 128 can be disposed vertically between the vertical transistors 126 and the pad-out interconnect layer 150. In some implementations, the interconnects in pad-out interconnect layer 150 can transfer electrical signals between the 3D semiconductor device 100 and outside circuits, e.g., for pad-out purposes.

In some implementations, the second semiconductor structure 104 further includes one or more contacts 152 extending through the substrate 148 and part of the pad-out interconnect layer 150 to couple the pad-out interconnect layer 150 to the DRAM cells 124 and the interconnect layer 122. As a result, the peripheral circuits 112 can be coupled to the DRAM cells 124 through the interconnect layers 116 and 122 as well as the bonding layers 120 and 118, and the peripheral circuits 112 and the DRAM cells 124 can be coupled to outside circuits through contacts 152 and pad-out interconnect layer 150. Contact pads 154 and contacts 152 can include conductive materials including, but not limited to, W, Co, Cu, Al, silicides, or any combination thereof. In one example, the contact pad 154 may include Al, and the contact 152 may include W. In some implementations, the contact 152 includes a via surrounded by a dielectric spacer (e.g., having silicon oxide) to electrically separate the via from substrate 148. Depending on the thickness of substrate 148, contact 152 can be an ILV having a depth in the submicron level (e.g., between 10 nm and 1 μm), or a TSV having a depth in the micron-or tens micron-level (e.g., between 1 μm and 100 μm).

Although not shown, it is understood that the pad-out of 3D memory devices is not limited to from the second semiconductor structure 104 having DRAM cells 124 as shown in FIG. 1 and may be from the first semiconductor structure 102 having peripheral circuit 112. Although not shown, it is also understood that the air gaps between word lines and/or between semiconductor bodies 130 may be partially or fully filled with dielectrics. Although not shown, it is further understood that more than one array of DRAM cells 124 may be stacked over one another to vertically scale up the number of DRAM cells 124.

In some implementations, instead of having the substrate 148 above the DRAM cells 124 as shown in FIG. 1, the second semiconductor structure 104 includes a substrate disposed below the DRAM cells 124. The substrate can be part of a carrier wafer. The DRAM cells 124 can be formed in a front side of the substrate, and the bit lines 123 can be formed in a back side of the substrate. The bit lines 123 can be conductively coupled to the DRAM cells 124 (e.g., the terminal structures 158 of the vertical transistors 126) through the substrate.

It is understood that FIG. 1 is for illustration propose only and the semiconductor device 100 can include an array of memory cells 124. Each of the array of memory cells 124 includes a vertical transistor 126 having a semiconductor body 130 and coupled to a corresponding bit line 123. Two adjacent memory cells 124 are separated by a dielectric structure 160 along the X direction.

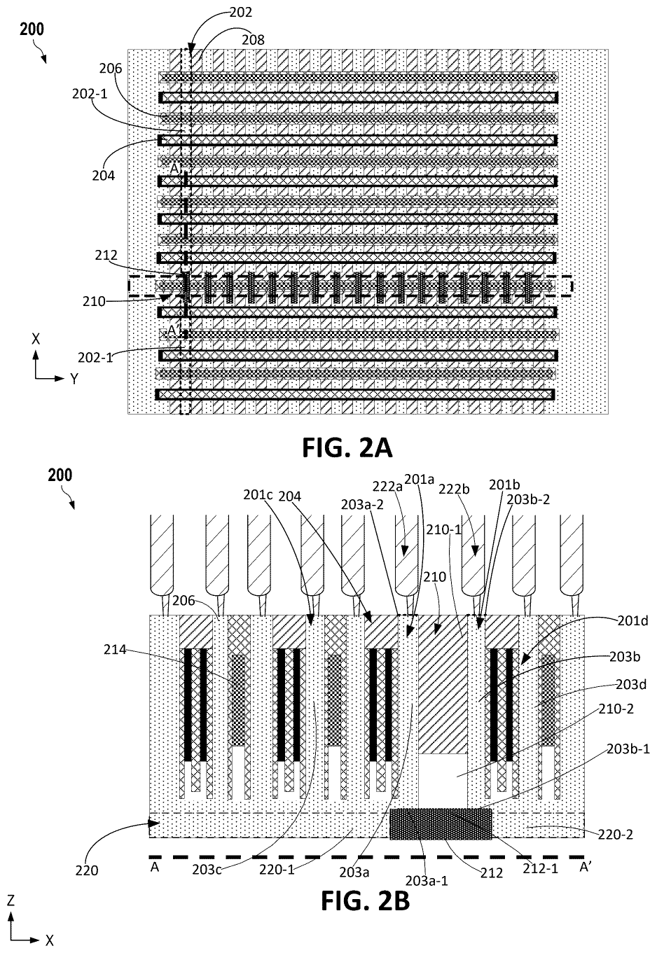

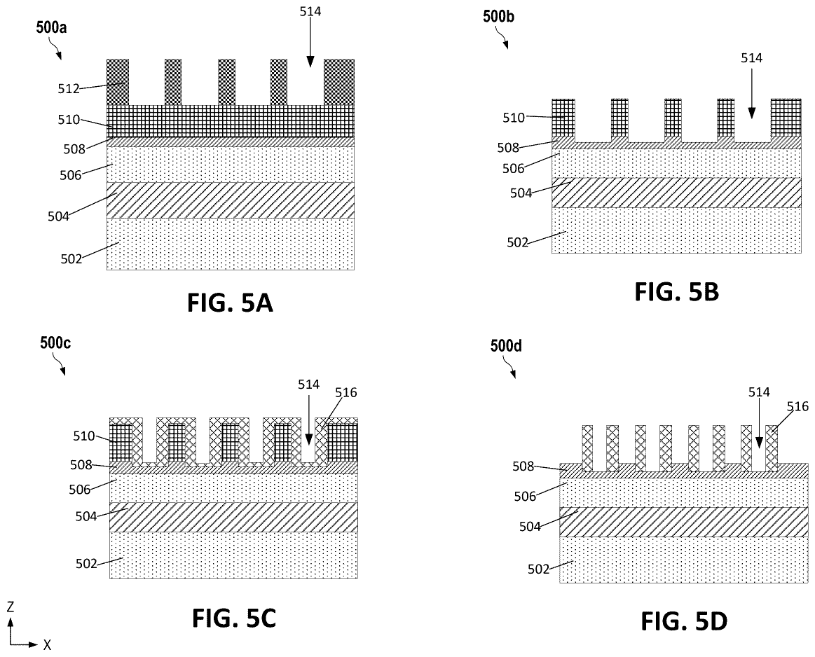

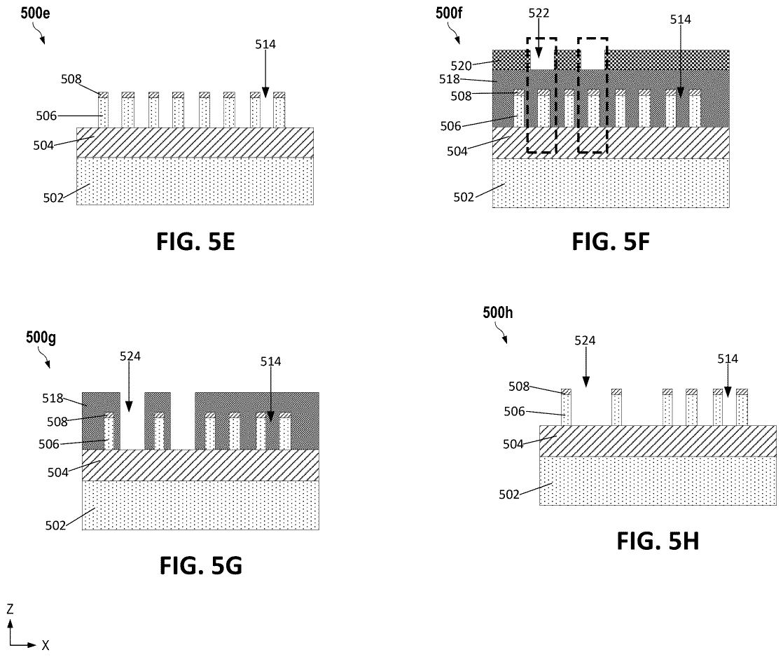

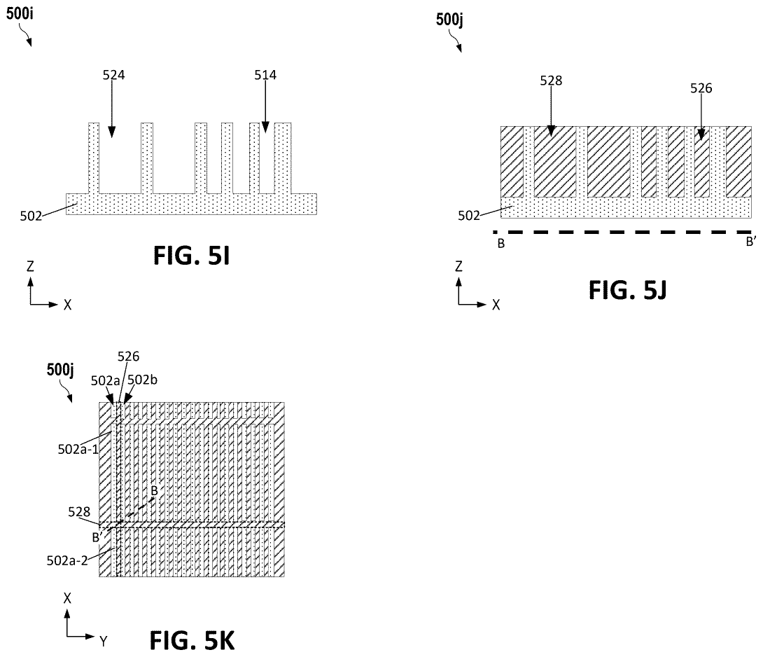

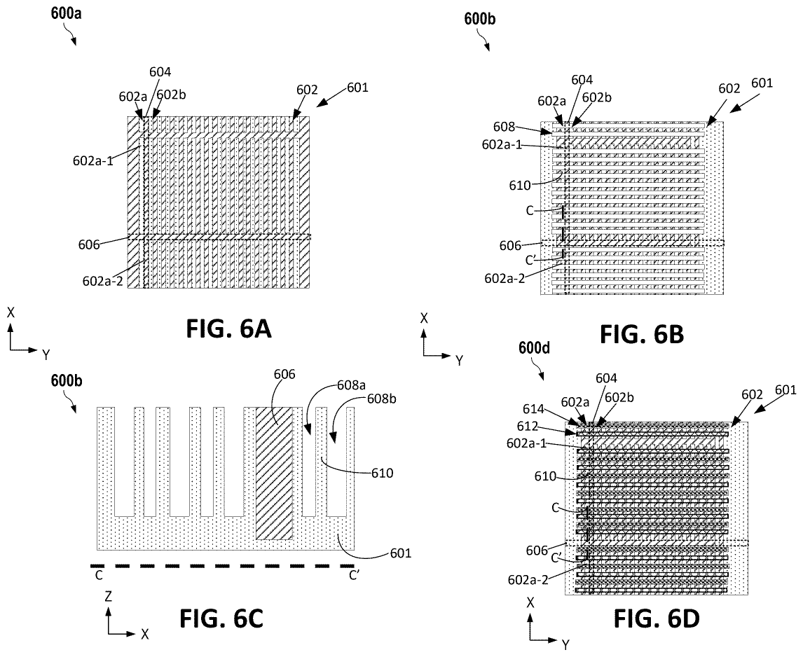

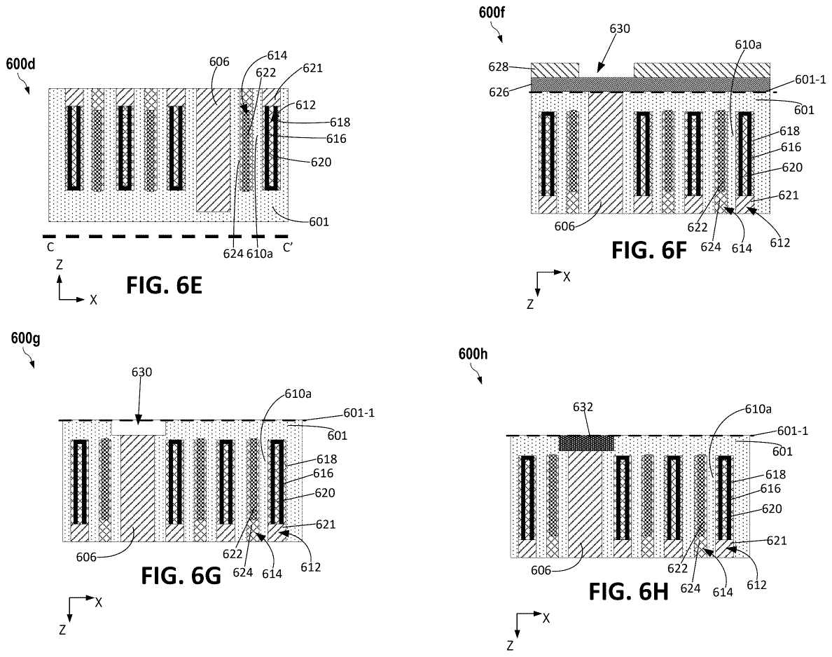

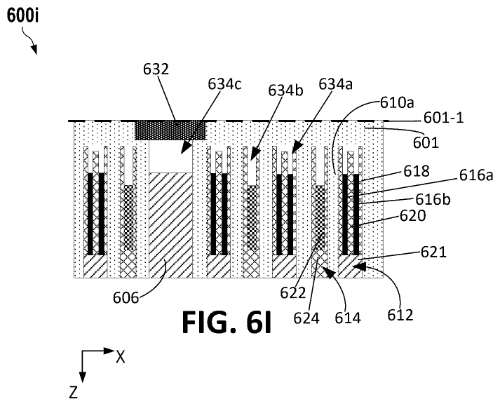

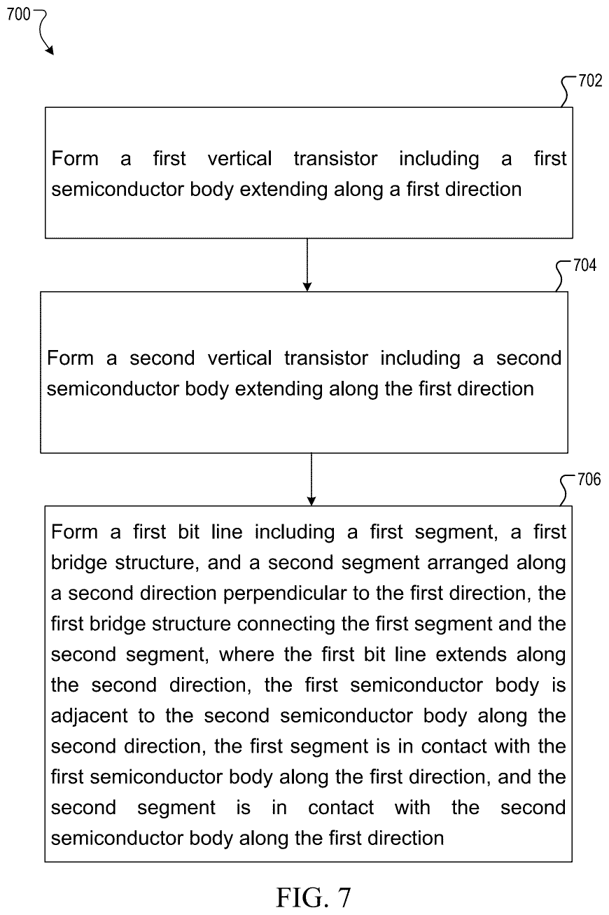

FIG. 2A illustrates a top view of the semiconductor device 200. The semiconductor device 200 can be the 3D semiconductor device 100 of FIG. 1 or a structure at an intermediate fabrication process of the 3D semiconductor device 100 of FIG. 1. The semiconductor device 200 can be formed by methods and/or processes described with further details in FIGS. 5A-5K and 6A-6I, and/or FIG. 7.

As shown in FIG. 2A, the semiconductor device 200 can include bit lines 202 extending along the X direction. As shown in FIG. 2A, two adjacent bit lines 202 are separated by a dielectric structure 208 along the Y direction. The dielectric structure 208 extends along the X direction and in contact with corresponding bit lines 202 along the Y direction. Each of the bit lines 202 includes at least a first segment 202-1 and a second segment 202-2. In some implementations, the first segment 202-1 and the second segment 202-2 of the bit line 202 are separated by an isolation structure 210. In some implementations, as shown in FIG. 2A, the isolation structure 210 extends along the Y direction and separates the bit lines 202 into two segments 202-1 and 202-2. As shown in FIG. 2A, the two segments 202-1 and 202-2 of the bit line 202 are connected by a bridge structure 212. The bridge structure extends along the X direction. In some implementations, the bridge structure 212 is in contact with the isolation structure 210 along the Z direction.

As shown in FIG. 2A, the semiconductor device 200 further includes first structures 204 and second structures 206 that are alternation with each other along the X direction. The first structures 204 and the second structures 206 extend along the Y direction. In some implementations, the first structures 204 can be similar to, or same as the first trench structure 137 of the semiconductor device 100 of FIG. 1. In some implementations, the second structure 206 can be similar to, or same as the dielectric structure 160 of the semiconductor device 100 of FIG. 1. In some implementations (not shown in FIG. 2A), the semiconductor device can further include vertical transistors having semiconductor bodies extending along the Z direction. Each of the semiconductor bodies of the vertical transistors are in contact with a corresponding bit line 202 along the Z direction. The first structures 204 can include gate structures that is coupled to a corresponding semiconductor body. Each of the second structures 206 can be configured to electrically isolate two adjacent semiconductor bodies of the vertical transistors along the X direction.

FIG. 2B illustrates a cross-section view of the semiconductor device 200 along cut line AA′ of FIG. 2A. As shown in FIG. 2B, the semiconductor device 200 can include a first vertical transistor 201a and a second vertical transistor 201b. In some implementations, the first vertical transistor 201a and the second vertical transistor 201b can be similar to, or same as vertical transistors 126a and 126b of the semiconductor 100 of FIG. 1. The first vertical transistor 201a includes a first semiconductor body 203a extending along the Z direction, and the second vertical transistor 201b includes a second semiconductor body 203b extending along the Z direction. The semiconductor device 200 also includes a first bit line 220. In some implementations, the first bit line 220 can be one of the bit lines 202 of FIG. 2A. In some implementations, the first bit line 220 can be similar to or same as the first bit line 123 of the semiconductor device 100 of FIG. 1. The first bit line extends along the X direction. In some implementations, the first bit line 220 includes a first segment 220-1, a first bridge structure 212, and a second segment 220-2 arranged along the X direction. As shown in FIG. 2B, the first bridge structure 212 connects the first segment 220-1 and the second segment 220-2 of the first bit line 220 along the X direction. It is understood that FIG. 2B is for illustration propose only and the first bit line 220 can include any number of segments, where two adjacent segments are connected by a corresponding first bridge structure 212. In some implementations, the segments 220-1 and 220-2 of the first bit line 220 can be used to relieve the internal stress during the fabrication process. In other words, the separation of the first bridge structure 212 can help the build in stress of the semiconductor device 200 during the fabrication process, resulting in a lower defect rate and leakage current.

As shown in FIG. 2B, the first semiconductor body 203a is adjacent to the second semiconductor body 203b along the X direction. The first segment 220-1 is in contact with a first side 203a-1 of the first semiconductor body 203a along the Z direction. The second segment 220-2 is in contact with a first side 203b-2 of the second semiconductor body 203b along the Z direction.

In some implementations, a length of the first bridge structure 212 is greater than a distance between the first semiconductor body 203a and the second semiconductor body 203b along the X direction, which ensures a stable connection between the first segment 220-1 and the second segment 220-2 of the first bit line 220. In some implementations, a width of the first bridge structure 212 is smaller or equal to a width of the first segment 220-1 of the first bit line 220 along the X direction. In some implementations, the cross-section of the first bridge structure 212 perpendicular to the Z direction can include, but not limited to the circular shape, the rectangular shape, the square shape or any other suitable shapes, where the first bridge structure 212 is in contact with the first segment 220-1 and the second segment 220-2 of the first bit line 220 along the X direction.

As shown in FIG. 2B, the semiconductor device 200 includes the isolation structure 210 extending along the Z direction. In some implementations, the isolation structure 210 is between the first semiconductor body 203a and the second semiconductor body 203b along the X direction. As shown in FIG. 2B, a portion of the isolation structure 210 includes a first separation structure 210-1 and a remaining portion of the isolation structure 210 includes an air gap 210-2 that is in contact with a side 212-1 of the bridge structure 212 along the Z direction. In some implementations, the air gap 210-2 is between the first semiconductor body 203a and the second semiconductor body 203b along the X direction.

In some implementations, the semiconductor device 200 further includes a first storage structure 222a and a second storage structure 222b. The first storage structure 222a is connected to a second side 203a-2 of the first semiconductor body 203a along the Z direction. The first side 203a-1 and the second side 203a-2 of the first semiconductor body 203a are on opposite side along the Z direction. The second storage structure 222b is connected to a second side 203b-2 of the second semiconductor body 203b along the Z direction. The first side 203b-1 and the second side 203b-2 of the second semiconductor body 203b are on opposite side along the Z direction.

In some implementations, the semiconductor device 200 further includes a third vertical transistors 201c and a fourth vertical transistor 201d. The third vertical transistor 201c includes a third semiconductor body 203c that extends along the Z direction. The third semiconductor body 203c is in contact with the first segment 220-1 of the first bit line 220. The fourth vertical transistor 201d includes a fourth semiconductor body 203d that extends along the Z direction. The fourth semiconductor body 203d is in contact with the second segment 220-2 of the first bit line 220. In some implementations, the first semiconductor body 203a and the second semiconductor body 203b are between the third semiconductor body 203c and the fourth semiconductor body 203d along the X direction. It is understood that FIG. 2B is for illustration propose only, and the semiconductor device 200 can include any number of the vertical transistors having semiconductor bodies that connect to the first segment 220-1 and the second segment 220-1 of the first bit line 220 along the Z direction. For example, the semiconductor device 200 can include an array of the vertical transistors having semiconductor bodies connected to the first bit line 220.

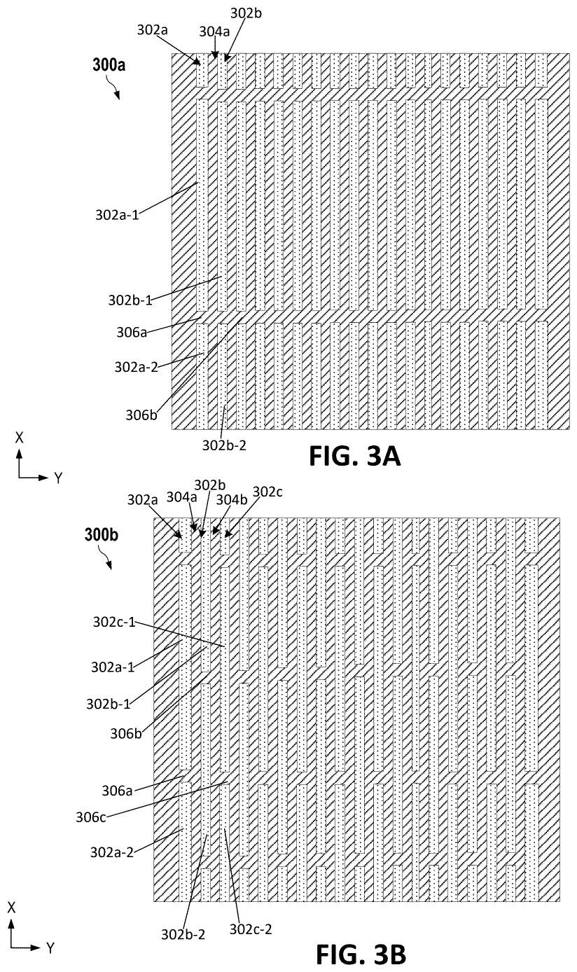

FIG. 3A illustrates a top view of an example semiconductor device 300a. The semiconductor device 300a can be the 3D semiconductor device 200 of FIG. 2A or a structure at an intermediate fabrication process of the 3D semiconductor device 200 of FIG. 2A. As shown in FIG. 3A, the semiconductor device 300a includes a first bit line 302a and a second bit line 302b. The first bit line 302a and the second bit line 302b extend along the X direction. In some implementations, the first bit line 302a and the second bit line 302b are separated by a first dielectric structure 304a. In some implementations, the first bit line 302a and the second bit line 302b can be similar to, or same as the bit lines 202 of the semiconductor device 200 of FIG. 2A.

As shown in FIG. 3A, the first bit line 302a includes at least a first segment 302a-1 and a second segment 302a-2 arranged along the X direction. The second bit line 302b includes at least a first segment 302b-1 and a second segment 302b-2 arranged along the X direction. In some implementations, the first segment 302a-1 and the second segment 302a-2 of the first bit line 302a are separated by an isolation structure 306a. The first segment 302b-1 and the second segment 302b-2 of the second bit line 302b are separated by an isolation structure 306b. In some implementations, the first segments 302a-1 and 302b-1 of the first bit line 302a and the second bit line 302b are aligned along the Y direction. The second segments 302a-2 and 302b-2 of the first bit line 302a and the second bit line 302b are aligned along the Y direction. For example, as shown in FIG. 1, the isolation structures 306a and 306b are aligned along the Y direction. In some implementations, the first bit line 302a and the second bit line 302b include more than two segments, where each of the segments of the bit line 302a is aligned with a corresponding segment of the second bit line 302b.

FIG. 3B illustrates a top view of an example semiconductor device 300b. The semiconductor device 300b can be similar to the semiconductor device 300a of FIG. 3A except the first bit line and the second bit line have different arrangements compared to the first bit line and the second bit line of the semiconductor device 300a of FIG. 3A.

As shown in FIG. 3B, the semiconductor device 300b further includes a third bit line 302c extending along the X direction. The third bit line 302c is separated from the second bit line 302b by a second dielectric structure 304b along the Y direction, where the second bit line 302b is between the first bit line 302a and the third bit line 302c along the Y direction. The third bit line 302c includes at least a first segment 302c-1 and a second segment 302c-2 separated by an isolation structure 306c along the X direction.

In some implementations, as shown in FIG. 3B, the first segments 302a-1, 302b-1, and 302c-1 of the first bit line 302a, the second bit line 302b, and the third bit line 302c are arranged in a staggered pattern, where the first segments 302a-1 and 302c-1 are aligned along the Y direction, and the first segments 302a-1 and 302b-1 are offset along the Y direction. In some implementations, the isolation structures 306a, 306b, and 306c are also arranged in the staggered pattern, where the isolation structures 306a and 306c are aligned along the Y direction and the isolation structures 306a and 306b are offset along the Y direction. In some implementations, as shown in FIG. 3B, the second segments 302b-1, 302 b-1, and 302b-1 of the first bit line 302a, the second bit line 302b, and the third bit line 302c are also arranged in the staggered pattern.

In some implementations (not shown in FIG. 3B), the first segments 302a-1, 302b-1, and 302c-1 of the first bit line 302a, the second bit line 302b, and the third bit line 302c are offset along the first direction.

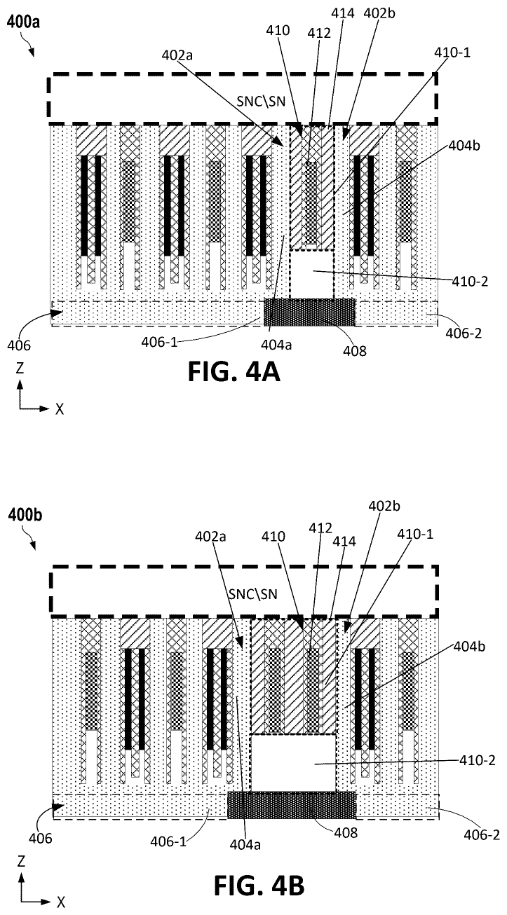

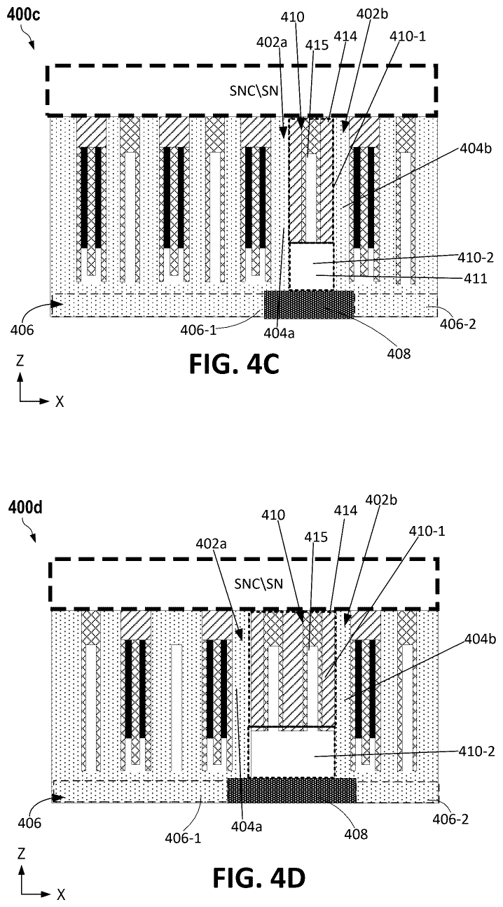

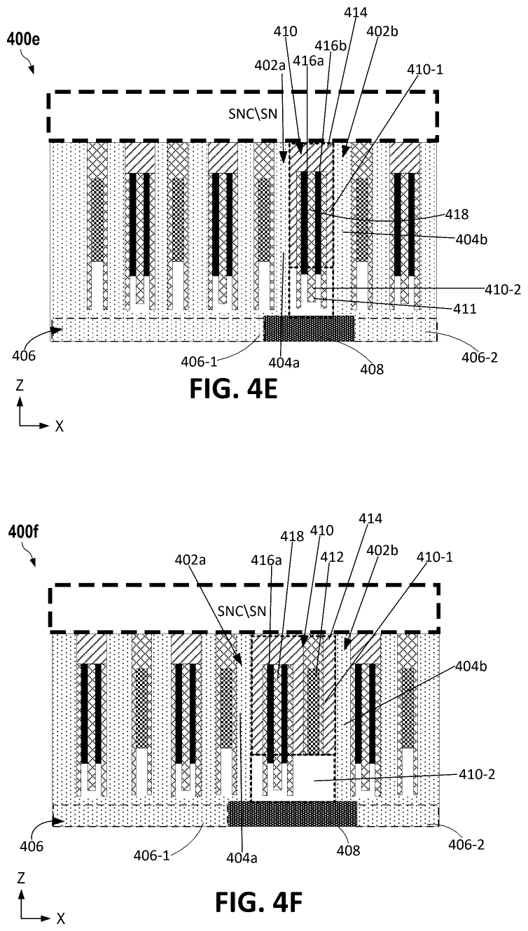

FIG. 4A illustrates a cross-section view of a semiconductor device 400a. The semiconductor device 400a can be similar to the semiconductor device 200a of FIG. 2B except that an isolation structure of the semiconductor device 400a has a different arrangement compared to the semiconductor device 200a of FIG. 2B.

The semiconductor device 400a includes a first vertical transistor 402a having a first semiconductor body 404a extending along the Z direction and a second vertical transistor 402b having a second semiconductor body 404b extending along the Z direction. The semiconductor device 400a also includes a first bit line 406 having a first segment 406-1, a bridge structure 408 and a second segment 406-2 arranged in the X direction. The bridge structure 408 connects the first segment 406-1 and the second segment 406-2 of the bridge structure 408.

The first bit line 406 extends along the X direction, where the first semiconductor body 404a is in contact with the first segment 406-1 along the Z direction and the second semiconductor body 404b is in contact with the second segment 406-2 along the Z direction. As shown in FIG. 4A, the semiconductor device also includes an isolation structure 410 extending along the Z direction. The isolation structure 410 is between the first semiconductor body 404a and the second semiconductor body 404b along the X direction. In some implementations, the isolation structure 410 includes a first portion 410-1 and a second portion 410-2. As shown in FIG. 4A, the first portion 410-1 of the isolation structure has a dielectric structure 412 surrounded by an outer layer 414. The dielectric structure 412 includes a dielectric material that is configured to electrically isolate the first semiconductor body 404a and the second semiconductor body 404b of the vertical transistors 402a and 402b along the X direction. The second portion 410-2 includes a first air gap 411 that is between the first semiconductor body 404a and the second semiconductor body 404b along the Y direction.

FIG. 4B illustrates a cross-section view of a semiconductor device 400b. The semiconductor device 400b can be similar to the semiconductor device 400a of FIG. 4A except that an isolation structure of the semiconductor device 400b has a different arrangement compared to the semiconductor device 400a of FIG. 4A. As shown in FIG. 4B, the first portion 410-1 of the isolation structure includes at least two dielectric structures 412. The two dielectric structures 412 are separated by the outer layer 414 along the X direction. In some implementations, the dielectric structures 412 can be used to electrically isolate the first semiconductor body 404a and the second semiconductor body 404b of the vertical transistors 402a and 402b along the X direction. Compared to the semiconductor device 400a, the arrangement of the isolation structure 410 of the semiconductor device 400b provides higher isolation capability.

FIG. 4C illustrates a cross-section view of a semiconductor device 400c. The semiconductor device 400c can be similar to the semiconductor device 400a of FIG. 4A except that an isolation structure of the semiconductor device 400c has a different arrangement compared to the semiconductor device 400a of FIG. 4A. As shown in FIG. 4C, the first portion 410-1 of the isolation structure includes a second air gap 415 that is surrounded by the outer layer 414. The second air gap 415 is connected to the first air gap 411 along the Z direction. In some implementations, the second air gap is configured to electrically isolate the first semiconductor body 404a and the second semiconductor body 404b of the vertical transistors 402a and 402b along the X direction. Compared to the semiconductor device 400a, the second air gap 415 can be fabricated along side the fabrication of the first air gap 411 during the fabrication process, which simplifies the manufacturing process.

FIG. 4D illustrates a cross-section view of a semiconductor device 400d. The semiconductor device 400d can be similar to the semiconductor device 400c of FIG. 4C except that an isolation structure of the semiconductor device 400d has a different arrangement compared to the semiconductor device 400c of FIG. 4C. As shown in FIG. 4D, the first portion 410-1 of the isolation structure includes at least two second air gaps 415. The two second air gaps 415 are separated by the outer layer 414 along the X direction. In some implementations, the two second air gaps 415 can be used to electrically isolate the first semiconductor body 404a and the second semiconductor body 404b of the vertical transistors 402a and 402b along the X direction. Compared to the semiconductor device 400c, the arrangement of the isolation structure 410 of the semiconductor device 400d provides higher isolation capability.

FIG. 4E illustrates a cross-section view of a semiconductor device 400e. The semiconductor device 400e can be similar to the semiconductor device 400a of FIG. 4A except that an isolation structure of the semiconductor device 400e has a different arrangement compared to the semiconductor device 400a of FIG. 4A. As shown in FIG. 4E, the first portion 410-1 of the isolation structure includes gate electrodes 416a and 416b extend along the Z direction. The gate electrodes 416a and 416b are separated by a dielectric layer 418. In some implementations, as shown in FIG. 4E, the gate electrodes 416a and 416b, and the dielectric layer 418 extend into the first air gap 411 along the Z direction. In some implementations, the gate electrode 416a is coupled to the first semiconductor body 404a of the first vertical transistor 402a, and the gate electrode 416b is coupled to the second semiconductor body 404b of second vertical transistor 402b. In some implementations, the gate electrodes 416a and 416b are configured to control the vertical transistors 402a and 402b.

FIG. 4F illustrates a cross-section view of a semiconductor device 400f. The semiconductor device 400f can be similar to the semiconductor device 400e of FIG. 4E except that an isolation structure of the semiconductor device 400f has a different arrangement compared to the semiconductor device 400e of FIG. 4E. As shown in FIG. 4F, the first portion 410-1 of the isolation structure 410 can include a group of the dielectric structure 412 and the gate electrodes 416a and 416b extend along the Z direction. The gate electrodes 416a and 416b are separated by the dielectric layer 418. In some implementations, the dielectric structure 412 and the gate electrodes 416a and 416b are separated by the outer layer 414 along the X direction. In some implementations, the dielectric structure 412 is configured to electrically isolate the first semiconductor body 404a and the second semiconductor body 404b of the vertical transistors 402a and 402b along the X direction. The gate electrode 416a is coupled to the first semiconductor body 404a of first vertical transistor 402a and configured to control the first vertical transistor 402a. It is understood that FIG. 4A-4F are for illustration propose only and the semiconductor devices 400a-f can have any arrangement of the isolation structure 410 for different functionality.

FIG. 5A-5K illustrate an example process of fabricating a semiconductor device, such as the semiconductor device 300a as illustrated in FIG. 3A. FIGS. 5A-5J show cross sectional views of example semiconductor structures at various stages of the fabrication process. FIG. 5K illustrate a top view of the example semiconductor structure during the fabrication process.

As shown in FIG. 5A, a semiconductor structure 500a is formed. The semiconductor structure 500a includes a substrate 502, a hard mask layer 504, and a second semiconductor layer 506 stacked on top of each other along a vertical direction (e.g., the Z direction). The semiconductor structure 500a also includes a first dielectric layer 508 stacked on top of the second semiconductor layer 506 along the Z direction, and a second dielectric layer 510 stacked on top of the first dielectric layer 508 along the Z direction. As shown in FIG. 5A, the hard mask layer 504 is between the substrate 502 and the second semiconductor layer 506 along the Z direction. The first dielectric layer 508 is between the second dielectric layer 510 and the second semiconductor layer 506 along the Z direction. The semiconductor structure 500a further includes a first sacrificial layer 512, which can be formed by depositing a first sacrificial material (e.g., photoresist material) on top of the second dielectric layer 510. In some implementations, the first sacrificial layer 512 includes first trenches 514, which can be formed by etching a portion of the first sacrificial layer 512 along the Z direction. In some implementations, as shown in FIG. 5A, the first trenches 514 are in contact with the second dielectric layer 510 along the Z direction.

FIG. 5B illustrates a semiconductor structure 500b, which can be formed by deepening the first trenches 514 along the Z direction. The deepening of the first trenches 514 is achieved by etching through the second dielectric layer 510 and into the first dielectric layer 508. In some implementations, as shown in FIG. 5B, the first sacrificial layer 512 is removed after the deepening of the first trenches 514. As shown in FIG. 5B, the first trenches 514 extend through the second dielectric layer 510 and into the first dielectric layer 508 along the Z direction.

FIG. 5C illustrates a semiconductor structure 500c, which can be formed by depositing a dielectric material on the second dielectric layer 510 and inner walls of the first trenches 514 to form a third dielectric layer 516.

FIG. 5D illustrates a semiconductor structure 500d, which can be formed by removing the second dielectric layer 510 and a portion of the third dielectric layer 516 through an etching process. The portion of the third dielectric layer 516 is in contact with the second dielectric layer 510 and on a bottom of each of the first trenches 514.

FIG. 5E illustrates a semiconductor structure 500e, which can be formed by deepening the first trenches 514 along the Z direction. The deepening of the first trenches 514 is achieved by etching through the first dielectric layer 508 and the second semiconductor layer 506 along the Z direction. The third dielectric layer 516 is used as a mask to protect a portion the first dielectric layer 508 and the second semiconductor layer 506 that is in contact with the third dielectric layer 516 along the Z direction. The third dielectric layer 516 can be removed after the deepening of the first trenches 514. As shown in FIG. 5E, the first trenches 514 extend through the first dielectric layer 508 and the second semiconductor layer 506 and are in contact with the hard mask layer 504 along the Z direction.

FIG. 5F illustrates a semiconductor structure 500f, which can be formed by depositing a second sacrificial material (e.g., carbon) on the first dielectric layer 508 and in the first trenches 514 to form a second sacrificial layer 518. As shown in FIG. 5F, a thickness of the second sacrificial layer 518 is greater than a length of the first trenches 514 along the Z direction to ensure the second sacrificial layer 518 encapsulates the first trenches along the Z direction. The semiconductor structure 500f includes a third sacrificial layer 520, which can be formed by depositing the first sacrificial material (e.g., photoresist material) on the second sacrificial layer 518. As shown in FIG. 5F, the semiconductor structure 500f includes second trenches 522, which can be formed by etching a portion of the third sacrificial layer 520 along the Z direction.

FIG. 5G illustrates a semiconductor structure 500g, which can be formed by deepening the second trenches 522 along the Z direction. The deepening of the second trenches 522 is achieved by etching through the second sacrificial layer 518, the first dielectric layer 508, and the second semiconductor layer 506. In some implementations, as shown in FIG. 5B, the third sacrificial layer 520 is used to protect a remaining portion of the second sacrificial layer 518 during the etching process and can be removed after the deepening of the second trenches 522. Sidewalls of a portion of the first trenches 514 are removed during the deepening of the second trenches 522, where two adjacent first trenches 514 are connected together to form third trenches 524. As shown in FIG. 5B, the third trenches 524 extend through the second sacrificial layer and are in contact with the hard mask layer 504 along the Z direction.

FIG. 5H illustrates a semiconductor structure 500h, which can be formed by removing the second sacrificial layer 518.

FIG. 5I illustrates a semiconductor structure 500i, which can be formed by deepening the first trenches 514 and the third trenches 524. The deepening of the first trenches 514 and the third trenches 524 is achieved by etching through the hard mask layer 504 and into the substrate 502 along the Z direction. As shown in FIG. 5I, the hard mask layer 504, the second semiconductor layer 506, and the first dielectric layer 508 are used to protect a first portion of the substrate 502 during the deepening the first trenches 514 and the third trenches 524, which are removed after the etching process. As shown in FIG. 5I, sidewalls of the first trenches 514 and the third trenches 524 includes the first portion of the substrate 502.

FIG. 5J illustrates a semiconductor structure 500j, which can be formed by filling a dielectric material (e.g., SiO₂) into the first trenches 514 and the third trenches 524 to form first isolation structures 526 and second isolation structures 528.

FIG. 5K illustrates a top view of the semiconductor structure 500j, where FIG. 5J illustrates a cross-section view of the semiconductor structure 500j along the cut line BB′ of FIG. 5K. As shown in FIG. 5K, the first isolation structures 526 extend along a horizontal direction (e.g., the X direction) perpendicular to the Z direction. The second isolation structure 528 extends along a second horizontal direction (e.g., the Y direction) perpendicular to the X direction and the Z direction). The first portion of the substrate 502 includes one or more columns extend along the X direction, and two adjacent columns of the first portion of the substrate 502 are separated by the first isolation structure 526 along the X direction. For example, as shown in FIG. 5K, the first portion of the substrate 502 includes a first column 502a and a second column 502b extend along the X direction. The first column 502a and the second column 502b are separated by the first isolation structure 526 along the Y direction. In some implementations, each of the columns of the first portion of the substrate 502 are separated into one or more segments along the X direction by the second isolation structure 528. For example, as shown in FIG. 5K, the first column 502a are separated into at least a first segment 502a-1 and a second segment 502a-2 that are separated by the second isolation structure 528. In some implementations, the separation of the columns of the substrate 502 is performed before the forming of the first isolation structure 526 and the second isolation structure 528. For example, the semiconductor structure 500i is formed before the semiconductor structure 500j during the fabrication to relieve the internal stress that is build up during the manufacturing process.

FIG. 6A-6I illustrate an example process of fabricating a semiconductor device, such as the semiconductor device 200 as illustrated in FIG. 2A. FIG. 6A-6J show cross sectional views or top views of example semiconductor structures at various stages of the fabrication process. In some implementations, the fabrication process shown in FIGS. 6A-6J is performed after the forming of the semiconductor structure 500j of FIG. 5J.

As shown in FIG. 6A, a semiconductor structure 600a is provided. The semiconductor structure 600a can be the semiconductor structure 500a as illustrated in FIG. 5K. The semiconductor structure 600a can include a substrate 601. In some implementations, the substrate 601 can be similar to, or same as the substrate 502 of FIG. 5K. A portion of the substrate 601 includes columns 602 extend along the X direction, where two adjacent columns 602 are separated by a first isolation structure 604. For example, as shown in FIG. 6A, the columns 602 includes a first column 602a and a second column 602b extend along the X direction. The first column 602a and the second column 602b are separated by the first isolation structure 604 along the Y direction. In some implementations, each of the columns of the first portion of the substrate 601 are separated into one or more segments along the X direction by the second isolation structure 606. For example, as shown in FIG. 6A, the first column 602a are separated into at least a first segment 602a-1 and a second segment 602a-2 that are separated by the second isolation structure 606. As shown in FIG. 6A, the first isolation structures 604 extend along the X direction, and the second isolation structure 606 extends along the Y direction.

FIG. 6B illustrates a semiconductor structure 600b, which can be formed by etching a portion of columns 602 and the first isolation structures 604 along the Z direction to form fourth trenches 608. The fourth trenches 608 extend along the Y direction and are separated from the second isolation structure along the X direction. In some implementations, the fourth trenches 608 separates etch of columns 602 into multiple semiconductor bodies 610.

FIG. 6C illustrates a cross-section view of the semiconductor structure 600b along cut line CC′. As shown in FIG. 6C, along the X direction, the semiconductor bodies 610 and the fourth trenches are alternating with etch other. In some implementations, the fourth trenches can include two groups 608a and 608b, where a width of the group 608a of the fourth trenches 608 is greater than a width of the group 608b of the fourth trenches 608. In some implementations, a height of the second isolation structure 606 is greater than a height of the fourth trenches 608 along the Z direction.

FIG. 6D illustrates a semiconductor structure 600d, which can be formed by forming first structures 612 in the group 608a of the fourth trenches 608 and second structures 614 in the group 608b of the fourth trenches 608. As shown in FIG. 6D, the first structures 612 and the second structures 614 are alternating with each other along the Y direction.

FIG. 6E illustrates a cross-section view of the semiconductor structure 600d along cut line DD'. As shown in FIG. 6E, the first structures 612 can be formed by depositing a first dielectric material, a conductive material, and a second dielectric into a portion of the group 608a of the fourth trenches 608 to form a first outer layer 618, a conductive layer 616 and a fourth dielectric layer 620. In some implementations, the first structures 612 also includes a first dielectric structure 621, which can be formed by filling a dielectric material in a remaining portion of the group 608a of the fourth trenches 608. As shown in FIG. 6E, a cross-section of the conductive layer 616 perpendicular to the Y direction has a U shape. The fourth dielectric layer 620 is surrounded by conductive layer 616. The conductive layers are separated from adjacent semiconductor bodies 610 by the first outer layer 618 along the X direction. In some implementations, each of the second structures 614 includes a second dielectric structure 622 surrounded by a second outer layer 624, which can be formed by depositing two different dielectric material into the group 608b of the fourth trenches 608, where one of the two different dielectric material surrounds a remaining dielectric material of the two different dielectric materials. As shown in FIG. 6E, a semiconductor body 610a is between a corresponding first structure 612 and a corresponding second structure 614 along the X direction.

FIG. 6F illustrates a semiconductor structure 600f, which can be formed by flipping the semiconductor structure 600d along the Z axis and thinning down the substrate 601 from an end 601-1 of the substrate 601. The end 601-1 and the first dielectric structure 621 are at opposite side of the substrate 601 along the Z direction. As shown in FIG. 6F, the second isolation structure 606 extends through the substrate 601 after the thinning process. The semiconductor structure 600f also includes a fourth sacrificial layer 626, which can be formed by depositing a first sacrificial material (e.g., carbon) on the end 601-1 of the substrate. As shown in FIG. 6F, the semiconductor structure 600f further includes a fifth sacrificial layer 628, which can be formed by depositing a second sacrificial material (e.g., photoresist material) on the fourth sacrificial layer 626. In some implementations, as shown in FIG. 6F, the semiconductor structure can include a fifth trench 630, which can be formed by etching a portion of the second sacrificial structure along the Z direction. As shown in FIG. 6F, the fifth trench 630 is in contact with the fourth sacrificial layer 626 along the Z direction. In some implementations, the fifth trench 630 and the second isolation structure are aligned along the X direction.

FIG. 6F illustrates a semiconductor structure 600f, which can be formed by deepening the fifth trench 630 along the Z direction. The deepening of the fifth trench 630 is achieved by etching through the fourth sacrificial layer 626 and etching a portion of the second isolation structure 606. The fourth sacrificial layer 626 and the fifth sacrificial layer 628 can be used as a mask layer to protect the substrate 601 during the deepening process and are removed after the etching process.

FIG. 6H illustrates a semiconductor structure 600h, which can be formed by filling the fifth trench with a conductive material 632 to form a conductive structure.

FIG. 6I illustrates a semiconductor structure 600i, which can be formed by etching a portion of the conductive layer 616 of the first structures 612, a proton of the second dielectric structure 622 of the second structures 614, and a portion of the second isolation structures 606 to form air gaps 634a, 634b, and 634c corresponding to the first structures 612, the second structures 614 and the second isolation structure 606. As shown in FIG. 6I, the conductive layer 616 of each of the first structures 612 is separated into two segments 616a and 616b. Each of the two segments 616a and 616b are coupled to a corresponding semiconductor body 610.

FIG. 7 illustrates a flow chart of an example process 700. The process 700 can be performed to form a semiconductor device (e.g., the semiconductor device 200 illustrated by FIG. 2B). The process 700 can be described in view of FIG. 5A-5K or FIG. 6A-6I. The process 700 can include one or more steps of the fabrication process of forming the semiconductor structures in FIG. 5A-5K or FIG. 6A-6I. It is understood that the operations shown in process 700 are not exhaustive and that other operations can be performed as well before, after, or between any of the illustrated operations. Further, some of the operations may be performed simultaneously, or in a different order than shown in FIG. 7.

At operation 702, a first vertical transistor (e.g., the first vertical transistor 201a of FIG. 2B) including a first semiconductor body (e.g., the first semiconductor body 203a of FIG. 2B) extending along a first direction (e.g., the Z direction) is formed.

At operation 704, a second vertical transistor (e.g., the second vertical transistor 201b of FIG. 2B) including a second semiconductor body (e.g., the second semiconductor body 203b of FIG. 2B) extending along the first direction is formed.

At operation 706, a first bit line (e.g., the first bit line 220 of FIG. 2B) is formed. The first bit line includes a first segment (e.g., the first segment 220-1 of FIG. 2B), a first bridge structure (e.g., the first bridge structure 212 of FIG. 2B), and a second segment (e.g., the second segment 220-2 of FIG. 2B) arranged along a second direction (e.g., the X direction) perpendicular to the first direction, the first bridge structure connecting the first segment and the second segment, where the first bit line extends along the second direction, the first semiconductor body is adjacent to the second semiconductor body along the second direction, the first segment is in contact with a first side of the first semiconductor body along the first direction, and the second segment is in contact with a first side the second semiconductor body along the first direction.

In some implementations, the method further includes providing a semiconductor substrate (e.g., the substrate 502 of FIG. 5A); etching a first portion of the semiconductor substrate from a first side of the semiconductor substrate to form first trenches (e.g., the first trenches 514 of FIG. 5A), where the first trenches extend along the second direction, where semiconductor structures are formed by a remaining portion of the semiconductor substrate; removing a portion of the semiconductor structures to form a second trench (e.g., the third trench 524 of FIG. 5H), where the second trench extends along a third direction (e.g., the Y direction) perpendicular to the first direction and the second direction; and filling a dielectric material in the first trenches and the second trench, where first isolation structures (e.g., the first isolation structures 526 of FIG. 5J) are defined by the dielectric material in the first trenches, and a second isolation structure (e.g., the second isolation structure 528 of FIG. 5J) is defined by the dielectric material in the second trench.

In some implementations, the method further includes etching a second portion of the semiconductor substrate from the first side of the semiconductor substrate to form third trenches (e.g., fourth trenches 608 of FIG. 6B), where the third trenches extend along the third direction; forming first structures (e.g., first structures 612 of FIG. 6D) in a portion of the third trenches, where each of the first structures includes two conductive structures (e.g., two segments 616a and 616b of FIG. 6I) the extending along the first direction, and where the two conductive structures are separated by an isolation structure (e.g., fourth dielectric layer 620 of FIG. 6E) along the second direction; and forming second structures (e.g., second structures 614 of FIG. 6D) in a remaining portion of the third trenches, where each of the second structures includes a dielectric structure.

In some implementations, the first bridge structure includes a conductive material, and where forming the first bridge structure includes thinning down the semiconductor substrate from a second side (e.g., the end 601-1 of FIG. 6F) of the semiconductor substrate, where the isolation structure extend through the semiconductor substrate, where the first side and the second side of the semiconductor substrate are on opposite side along the first direction; etching a third portion of the semiconductor substrate and a portion of the isolation structure from the second side to form a fourth trench (e.g., the fifth trench 630 of FIG. 6G); and depositing the conductive material in the fourth trench to form the first bridge structure.

In some implementations, the method further includes removing a portion of the first structure from an end of the first structure to from a first space (e.g., the air gap 634a of FIG. 6I), the end of the first structure being closer to the second side of the semiconductor substrate than the first side of the semiconductor substrate; removing a portion of the second structure from an end of the second structure to from a second space (e.g., the air gap 634b of FIG. 6I), the end of the second structure being closer to the second side of the semiconductor substrate than the first side of the semiconductor substrate; and removing a portion of the isolation structure from an end of the isolation structure to from a third space (e.g., the air gap 634c of FIG. 6I), the end of the isolation structure being closer to the second side of the semiconductor substrate than the first side of the semiconductor substrate.

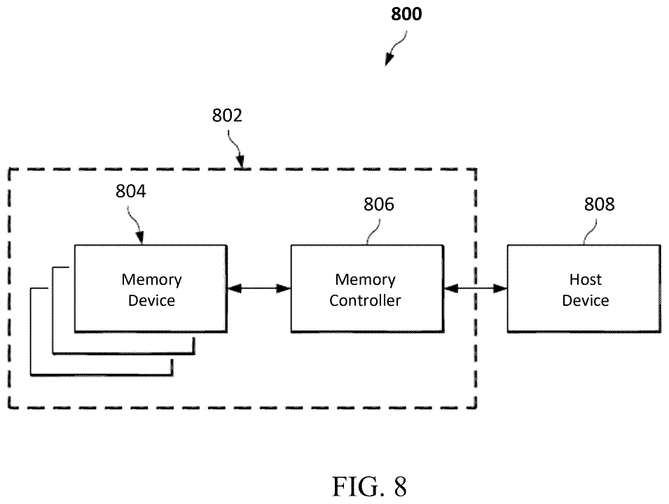

FIG. 8 illustrates a block diagram of a system 800 having one or more semiconductor devices (e.g., memory devices), according to one or more implementations of the present disclosure. The system 800 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 8, the system 800 can include a host device 808 and a memory system 802 having one or more 3D memory devices 804 and a memory controller 806. Host device 808 can include a processor of an electronic device, such as a central processing unit (CPU), or a system-on-chip (SoC), such as an application processor (AP). Host device 808 can be configured to send or receive data to or from the one or more 3D memory devices 804.

A 3D memory device 804 can be any 3D memory device disclosed herein, such as a 3D memory device depicted in FIGS. 1, 2A-2B. In some implementations, a 3D memory device 804 includes a DRAM memory. Memory controller 806 (a.k.a., a controller circuit) is coupled to 3D memory device 804 and host device 808. Consistent with implementations of the present disclosure, 3D memory device 804 can include a plurality of conductive interconnections through a cover layer that are in contact with conductive pads in a conductive pad layer, and memory controller 806 can be coupled to 3D memory device 804 through at least one of the plurality of conductive interconnections. Memory controller 806 is configured to control 3D memory device 804. For example, memory controller 806 may be configured to operate a plurality of channel structures via word lines. Memory controller 806 can manage data stored in 3D memory device 804 and communicate with host device 808.

In some implementations, memory controller 806 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 806 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 806 can be configured to control operations of 3D memory device 804, such as read, erase, and program (or write) operations. Memory controller 806 can also be configured to manage various functions with respect to the data stored or to be stored in 3D memory device 804 including, but not limited to bad-block management, garbage collection, logical-to-physical address conversion, wear leveling, etc. In some implementations, memory controller 806 is further configured to process error correction codes (ECCs) with respect to the data read from or written to 3D memory device 804. Any other suitable functions may be performed by memory controller 806 as well, for example, formatting 3D memory device 804.

Memory controller 806 can communicate with an external device (e.g., host device 808) according to a particular communication protocol. For example, memory controller 806 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 806 and one or more 3D memory devices 804 can be integrated into various types of storage devices, for example, be included in the same package, such as a universal Flash storage (UFS) package or an eMMC package. That is, memory system 802 can be implemented and packaged into different types of end electronic products. In one example as shown in FIG. 8, memory controller 806 and a single 3D memory device 804 may be integrated into a memory card 802. Memory card 802 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g.,.+−.10%,.+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

1. A semiconductor device, comprising:
a first vertical transistor comprising a first semiconductor body extending along a first direction;
a second vertical transistor comprising a second semiconductor body extending along the first direction; and
a first bit line comprising a first segment, a first bridge structure, and a second segment arranged along a second direction perpendicular to the first direction, the first bridge structure connecting the first segment and the second segment, wherein:
the first bit line extends along the second direction, the first semiconductor body is adjacent to the second semiconductor body along the second direction, the first segment is in contact with a first side of the first semiconductor body along the first direction, and the second segment is in contact with a first side the second semiconductor body along the first direction.

2. The semiconductor device of claim 1, wherein a length of the first bridge structure is greater than a distance between the first semiconductor body and the second semiconductor body along the second direction.

3. The semiconductor device of claim 1, wherein a width of the first bridge structure is smaller or equal to a width of the first segment of the first bit line along a third direction perpendicular to the first direction and the second direction.

4. The semiconductor device of claim 1, wherein a cross-section of the first bridge structure perpendicular to the second direction comprises a rectangular shape.

5. The semiconductor device of claim 1, further comprising:
an isolation structure extending along the first direction, wherein the isolation structure is between the first semiconductor body and the second semiconductor body along the second direction.

6. The semiconductor device of claim 5, wherein the isolation structure comprises:
a first separation structure in at least a portion of the isolation structure; and
an air gap that is in contact with a side of the bridge structure along the first direction, wherein the air gap is between the first semiconductor body and the second semiconductor body along the second direction.

7. The semiconductor device of claim 6, wherein the semiconductor device comprises a first gate electrode extending along the first direction coupled to the first semiconductor body, wherein the first gate electrode comprises a first end and a second end opposite to each along the first direction, wherein an end of the air gap is between the first end and the second end of the first gate electrode, and wherein the end of the air gap is in contact with the first separation structure along the first direction.

8. The semiconductor device of claim 6, wherein the first separation structure of the isolation structure further comprises:
a second gate electrode extending along the first direction, wherein the second gate electrode is coupled to the first semiconductor body; and
a third gate electrode extending along the first direction, wherein the third gate electrode is coupled to the second semiconductor body, and wherein the second gate electrode and the third gate electrode are separated by a first dielectric structure.

9. The semiconductor device of claim 6, wherein the first separation structure of the isolation structure further comprises a second dielectric structure extending along the first direction, wherein the second dielectric structure electrically isolates the first semiconductor body and the second semiconductor body.

10. The semiconductor device of claim 6, wherein the first separation structure of the isolation structure comprises a group of at least one third dielectric structure extending along the first direction and at least one fourth gate electrode extending along the first direction,
wherein the third dielectric structure electrically isolates the first semiconductor body and the second semiconductor body, and
wherein the fourth gate electrode is coupled to either the first semiconductor body or the second semiconductor body.

11. The semiconductor device of claim 1, wherein the semiconductor device further comprises:
a third vertical transistor comprising a third semiconductor body extending along a first direction;
a fourth vertical transistor comprising a fourth semiconductor body extending along the first direction, the third semiconductor body is adjacent to the fourth semiconductor body along the second direction; and
a second bit line extending the second direction, wherein the second bit line comprises a third segment, a second bridge structure, and a fourth segment arranged along the second direction, the third segment is in contact with the third semiconductor body along the first direction, and the fourth segment is in contact with the fourth semiconductor body along the first direction,
wherein the second bridge structure connects the third segment and the fourth segment, wherein the first bit line and the second bit line are separated by a first dielectric structure along a third direction perpendicular to the first direction and the second direction, and the first bridge structure of the first bit line and the second bridge structure of the second bit line are aligned along the third direction.

12. The semiconductor device of claim 1, wherein the semiconductor device further comprises:
a fifth vertical transistor comprising a fifth semiconductor body extending along a first direction;
a sixth vertical transistor comprising a sixth semiconductor body extending along the first direction, the fifth semiconductor body is adjacent to the sixth semiconductor body along the second direction; and
a third bit line extending the second direction, wherein the third bit line comprises a fifth segment, a third bridge structure, and a sixth segment arranged along the second direction, the fifth segment is in contact with the fifth semiconductor body along the first direction, and the sixth segment is in contact with the sixth semiconductor body along the first direction,
wherein the third bridge structure connects the fifth segment and the sixth segment, wherein the first bit line and the third bit line are separated by a second dielectric structure along a third direction perpendicular to the first direction and the second direction, and the first bridge structure of the first bit line and the third bridge structure of the third bit line are offset along the third direction.

13. The semiconductor device of claim 1, wherein:
the first vertical transistor further comprises a first storage structure connected to a second side of the first semiconductor body along the first direction, wherein the first side and the second of the first semiconductor body are on opposite side along the first direction; and
the second vertical transistor further comprises a second storage structure connected to a second side of the second semiconductor body along the first direction, wherein the first side and the second of the second semiconductor body are on opposite side along the first direction.

14. The semiconductor device of claim 1, further comprising:
a seventh vertical transistor comprising a seventh semiconductor body extending along the first direction, wherein the seventh semiconductor body is in contact with the first segment of the first bit line; and
an eighth vertical transistor comprising an eighth semiconductor body extending along the first direction, wherein the eighth semiconductor body is in contact with the second segment of the first bit line, and wherein the first semiconductor body and the second semiconductor body are between the seventh semiconductor body and the eighth semiconductor body along the second direction.

15. A method, comprising:
forming a first vertical transistor comprising a first semiconductor body extending along a first direction;
forming a second vertical transistor comprising a second semiconductor body extending along the first direction; and
forming a first bit line comprising a first segment, a first bridge structure, and a second segment arranged along a second direction perpendicular to the first direction, the first bridge structure connecting the first segment and the second segment, wherein:
the first bit line extends along the second direction, the first semiconductor body is adjacent to the second semiconductor body along the second direction, the first segment is in contact with a first side of the first semiconductor body along the first direction, and the second segment is in contact with a first side the second semiconductor body along the first direction.

16. The method of claim 15, further comprising:
providing a semiconductor substrate;
etching a first portion of the semiconductor substrate from a first side of the semiconductor substrate to form first trenches, wherein the first trenches extend along the second direction, wherein semiconductor structures are formed by a remaining portion of the semiconductor substrate;
removing a portion of the semiconductor structures to form a second trench, wherein the second trench extends along a third direction perpendicular to the first direction and the second direction; and
filling a dielectric material in the first trenches and the second, wherein first isolation structures are defined by the dielectric material in the first trenches, and a second isolation structure is defined by the dielectric material in the second trench.

17. The method of claim 16, wherein the method further comprises:
etching a second portion of the semiconductor substrate from the first side of the semiconductor substrate to form third trenches, wherein the third trenches extend along the third direction;
forming first structures in a portion of the third trenches, wherein each of the first structures includes two conductive structures extending along the first direction, and wherein the two conductive structures are separated by an isolation structure along the second direction; and
forming second structures in a remaining portion of the third trenches, wherein each of the second structures includes a dielectric structure.

18. The method of claim 17, wherein the first bridge structure comprises a conductive material, and wherein forming the first bridge structure comprises:
thinning down the semiconductor substrate from a second side of the semiconductor substrate, where the isolation structure extend through the semiconductor substrate, wherein the first side and the second side of the semiconductor substrate are on opposite side along the first direction;
etching a third portion of the semiconductor substrate and a portion of the isolation structure from the second side to form a fourth trench; and
depositing the conductive material in the fourth trench to form the first bridge structure.

19. The method of claim 18, further comprising:
removing a portion of the first structure from an end of the first structure to from a first space, the end of the first structure being closer to the second side of the semiconductor substrate than the first side of the semiconductor substrate;
removing a portion of the second structure from an end of the second structure to from a second space, the end of the second structure being closer to the second side of the semiconductor substrate than the first side of the semiconductor substrate; and
removing a portion of the isolation structure from an end of the isolation structure to from a third space, the end of the isolation structure being closer to the second side of the semiconductor substrate than the first side of the semiconductor substrate.

20. A memory system, comprising:
a memory device; and
a memory controller coupled to the memory device and configured to control the memory device,
wherein the memory device comprises:
a first vertical transistor comprising a first semiconductor body extending along a first direction;
a second vertical transistor comprising a second semiconductor body extending along the first direction; and
a first bit line comprising a first segment, a first bridge structure, and a second segment arranged along a second direction perpendicular to the first direction, the first bridge structure connecting the first segment and the second segment, wherein:
the first bit line extends along the second direction, the first semiconductor body is adjacent to the second semiconductor body along the second direction, the first segment is in contact with a first side of the first semiconductor body along the first direction, and the second segment is in contact with a first side the second semiconductor body along the first direction.
